(19) United States
(12) Patent Application Publication
(10) Pub. No.: US 2018/0330494 A1
(43) Pub. Date: Nov. 15, 2018

(54) METHOD OF DETECTING DEFECT OF CONTACT HOLE

(71) Applicant: NGR Inc., Yokohama (JP)

(72) Inventors: Kazuto TANAKA, Yokohama (JP); Sumio SASAKI, Yokohama (JP); Yoshishige SATO, Yokohama (JP)

(21) Appl. No.: 15/971,685

(22) Filed: May 4, 2018

(30) Foreign Application Priority Data
May 9, 2017 (JP) 2017-92965

(51) Int. Cl. G06T 7/00; H01L 21/66; H01J 37/22

(52) U.S. Cl. CPC G06T 7/0006; H01J 37/28; H01J 37/222; H01L 22/12

(57) ABSTRACT

A method capable of accurately detecting a defect of a contact hole by using voltage contrast images is disclosed. This method includes: obtaining a plurality of voltage contrast images generated at different points in time; calculating average brightness levels of respective contact holes on each of the plurality of voltage contrast images; calculating a brightness index value which is an average of the average brightness levels of respective contact holes on each of the plurality of voltage contrast images; calculating a difference between an average brightness level of each contact hole on each voltage contrast image and the brightness index value that has been calculated for that voltage contrast image; calculating a sum of the differences that have been calculated for contact holes located at the same position in the plurality of voltage contrast images; comparing the sum of the differences with a defect threshold value; and detecting a defect of a contact hole with which the sum of the differences is larger than the defect threshold value.

### CROSS REFERENCE TO RELATED APPLICATION

This document claims priority to Japanese Patent Application No. 2017-92965 filed May 9, 2017, the entire contents of which are hereby incorporated by reference.

### BACKGROUND

For inspection of wafers in manufacturing process of semiconductor integrated circuits, there is an interconnect defect detection method using a voltage contrast image generated by a scanning electron microscope. For example, Japanese Laid-Open Patent Application No. 10-294344 discloses a technique for use in defect inspection in a contact hole.

The contact hole is a hole formed in a dielectric film lying between layers of a semiconductor integrated circuit. The contact hole is filled with a metal interconnect, which electrically connects circuits between the respective layers. If the bottom of the contact hole does not extend through the dielectric film and does not reach an underlying conductive layer, the circuits cannot be connected with the metal interconnect, resulting in a defect.

According to the method disclosed in the Japanese Laid-Open Patent Application No. 10-294344, a defect of a contact hole is detected by determining whether a brightness of a contact hole is higher than that of a normal contact hole on a voltage contrast image.

However, electrical characteristics change depending on physical properties of the circuit. As a result, it takes a certain time until a potential distribution generated in the dielectric film by irradiation of an electron beam becomes an equilibrium state. Since the voltage contrast image reflects the potential distribution at a certain point in time, a difference in the brightness may not appear between a normal contact hole and a defective contact hole.

### SUMMARY OF THE INVENTION

Thus, according to an embodiment, there is provided a method capable of accurately detecting a defect of a contact hole by using voltage contrast images.

Embodiment, which will be described below, relate to a method of detecting a defect in a contact hole, and more specifically relate to a method of detecting a defect in a contact hole that has been formed in a dielectric film on the basis of design data. Such a dielectric form may constitute, for example, a semiconductor integrated circuit (LSI) or a liquid crystal panel.

In an embodiment, there is provided a method of detecting a defect of a contact hole, comprising: obtaining a plurality of voltage contrast images generated at different points in time; calculating average brightness levels of respective contact holes on each of the plurality of voltage contrast images; calculating a brightness index value which is an average of the average brightness levels of respective contact holes on each of the plurality of voltage contrast images; calculating a difference between an average brightness level of each contact hole on each voltage contrast image and the brightness index value that has been calculated for that voltage contrast image; calculating a sum of the differences that have been calculated for contact holes located at the same position in the plurality of voltage contrast images; comparing the sum of the differences with a defect threshold value; and detecting a defect of a contact hole with which the sum of the differences is larger than the defect threshold value.

In an embodiment, said obtaining the plurality of voltage contrast images comprises obtaining a plurality of voltage contrast images generated at constant time intervals within a preset period of time.

According to the embodiments described above, the defect of the contact hole is detected with use of the brightness of the contact hole on the voltage contrast images that have been generated at different points in time. Therefore, even if the brightness of the contact hole changes with the lapse of time, the defect of the contact hole can be accurately detected.

### BRIEF DESCRIPTION OF THE DRAWINGS

FIG. 1 is a schematic diagram showing an embodiment of an inspection apparatus;

FIG. 2 is a schematic diagram showing an embodiment of an image generating device of the inspection apparatus;

FIG. 3 is a flowchart showing an embodiment of a method of detecting a defect of a contact hole;

FIG. 4 is a conceptual diagram of step 1 of the flowchart shown in FIG. 3;

FIG. 5 is a conceptual diagram of step 2 of the flowchart shown in FIG. 3;

FIG. 6 is a conceptual diagram of step 3 of the flowchart shown in FIG. 3;

FIG. 7 is a conceptual diagram of step 4 of the flowchart shown in FIG. 3;

FIG. 8 is a plan view of a plurality of contact holes formed in a dielectric film;

FIG. 9 is a cross-sectional view taken along line A-A of FIG. 8;

FIG. 10 is a cross-sectional view of a wafer surface at a point in time when generation of the voltage contrast image is started;

FIG. 11 is a schematic view showing a state immediately after an electron beam irradiates a contact hole in which a residue of a dielectric film exists on a bottom of the contact hole;

FIG. 12 is a schematic diagram showing a state in which a potential difference disappears in the dielectric film as a result of continuously generating voltage contrast images; and

FIG. 13 is a schematic view showing a state in which a positively charged layer is formed in the residue of the dielectric film constituting the bottom of the contact hole as a result of further continuing generation of the voltage contrast images.

### DESCRIPTION OF EMBODIMENTS

Embodiments will be now described with reference to the drawings.

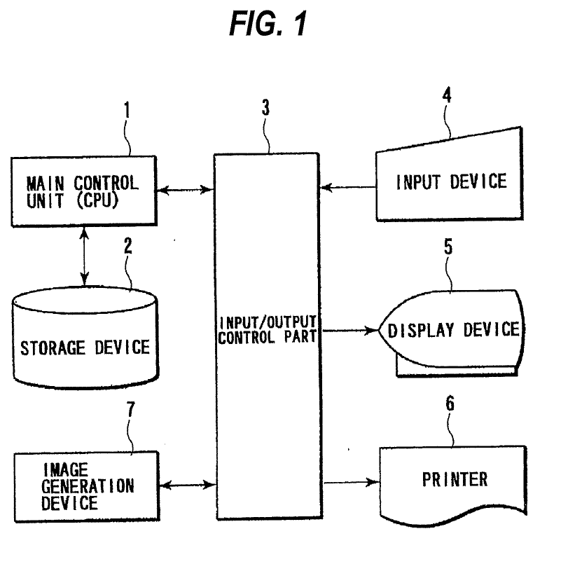

FIG. 1 is a schematic diagram showing an embodiment of an inspection apparatus. The inspection apparatus according to this embodiment comprises a main control unit 1, a storage device 2, an input/output control unit 3, an input device 4, a display device 5, a printer 6, and an image generation device 7.

The main control unit 1 comprises a CPU (Central Processing Unit), and is configured to manage and control the whole apparatus. The main control unit 1 is coupled to the storage device 2. The storage device 2 may be in the form of a hard disk, a flexible disk, an optical disk, or the like. The input device 4 such as a keyboard and a mouse, the display device 5 such as a display for displaying input data, calculation results, and the like, and the printer 6 for printing inspection results and the like are coupled to the main control unit 1 through the input/output control unit 3.

The main control unit 1 has an internal memory (internal storage device) for storing a control program such as an OS (Operating System), a program for inspecting a contact hole, necessary data, and the like. The main control unit 1 is configured to realize the inspection of the contact hole and extraction of sampling points with these programs. These programs can be initially stored in a flexible disk, an optical disk, or the like, read and stored in a memory, a hard disk, and the like before execution, and then executed.

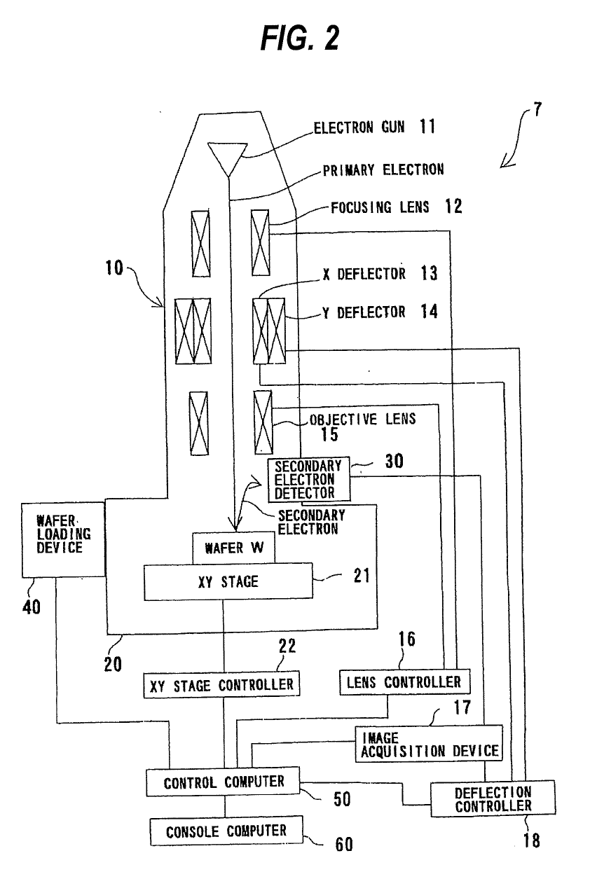

FIG. 2 is a schematic diagram of an embodiment of the image generation device 7 of the inspection apparatus. As shown in FIG. 2, the image generation device 7 includes an irradiation system 10, a specimen chamber 20, and a secondary electron detector 30. In this embodiment, the image generation device 7 comprises a scanning electron microscope.

The irradiation system 10 includes an electron gun 11, a focusing lens 12 for focusing primary electrons emitted from the electron gun 11, an X deflector 13 and a Y deflector 14 for deflecting an electron beam (charged-particle beam) in the X direction and the Y direction, respectively, and an objective lens 15. The specimen chamber 20 has an XY stage 21 which is movable in the X direction and the Y direction. A wafer W, which is a specimen, can be loaded into and unloaded from the specimen chamber 20 by a wafer-loading device 40.

In the irradiation system 10, primary electrons, emitted from the electron gun 11, are focused by the focusing lens 12, deflected by the X deflector 13 and the Y deflector 14, and focused by the objective lens 15 to irradiate the surface of the wafer W.

When the primary electrons strike the wafer W, the wafer W emits secondary electrons. These secondary electrons are detected by the secondary electron detector 30. The focusing lens 12 and the objective lens 15 are coupled to a lens controller 16, which is coupled to a control computer 50. The secondary electron detector 30 is coupled to an image acquisition device 17, which is also coupled to the control computer 50. Intensities of the secondary electrons detected by the secondary electron detector 30 are converted into a voltage contrast image by the image acquisition device 17. A field of view is defined as the largest region where the primary electrons are applied and a voltage contrast image without distortion can be acquired.

The X deflector 13 and the Y deflector 14 are coupled to a deflection controller 18, which is also coupled to the control computer 50. The XY stage 21 is coupled to an XY stage controller 22. This XY stage controller 22 is also coupled to the control computer 50. The wafer-loading device 40 is also coupled to the control computer 50. The control computer 50 is coupled to a console computer 60.

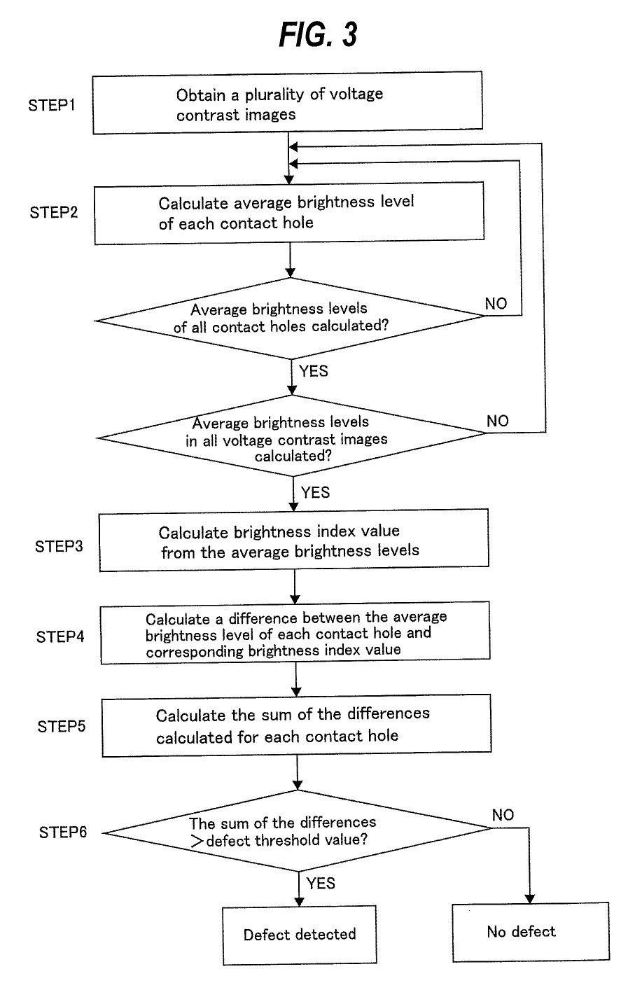

FIG. 3 is a flowchart showing an embodiment of a method of detecting a defect of a contact hole. The defect detection of the contact hole is executed by the main control unit 1 shown in FIG. 1. The main control unit 1 obtains, from the image generating device 7, a plurality of voltage contrast images that have been generated at different points in time within a preset period of time (step 1). In one embodiment, the main control unit 1 may obtain, from the image generating device 7, a plurality of voltage contrast images that have been generated at constant time intervals within a preset period of time.

Next, the main control unit 1 calculates average brightness levels, each of which is an average of brightness of each one of contact holes that appear on each of the plurality of voltage contrast images (step 2). Next, the main control unit 1 calculates a brightness index value which is an average of the average brightness levels of the plurality of contact holes on each voltage contrast image (step 3). The main control unit 1 calculates a difference between the average brightness level of each contact hole on each voltage contrast image and the brightness index value calculated for that voltage contrast image (step 4).

The main control unit 1 calculates the sum of the differences calculated respectively for the contact holes located at the same position in the plurality of contrast images (step 5). Further, the main control unit 1 compares the sum of the differences with a defect threshold value, and detects a defect of a contact hole with which the sum of the differences is larger than the defect threshold value (step 6). When the sum of the differences is smaller than the defect threshold value, the main control unit 1 determines that there is no defect in the contact hole.

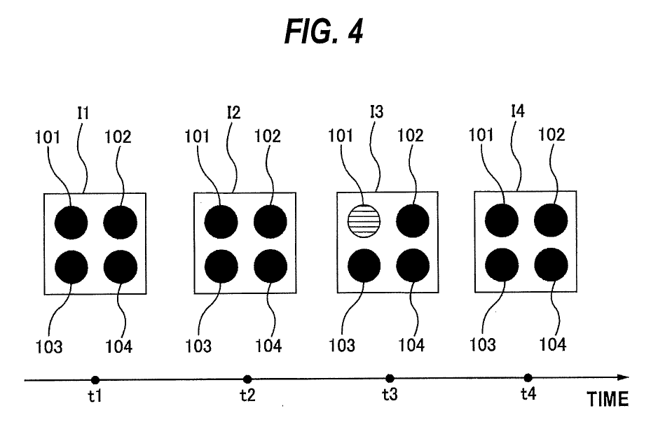

FIG. 4 is a conceptual diagram of the step 1 shown in FIG. 3. The main control unit 1 obtains, from the image generating device 7, a plurality of voltage contrast images I1, I2, I3, and I4 that have been generated at different points in time t1, t2, t3, and t4 within a preset period of time. As shown in FIG. 4, the plurality of voltage contrast images I1, I2, I3, and I4 have been generated along a time axis. The voltage contrast images I1, I2, I3, and I4 may be generated at constant time intervals.

Each of the voltage contrast images I1, I2, I3, and I4 contains images of contact holes, i.e., a first contact hole 101, a second contact hole 102, a third contact hole 103, and a fourth contact hole 104. In the present embodiment, four voltage contrast images are obtained. However, it is noted that the number of voltage contrast images used for the defect detection of contact holes is not limited to this embodiment. For example, the main control unit 1 may obtain more than four voltage contrast images.

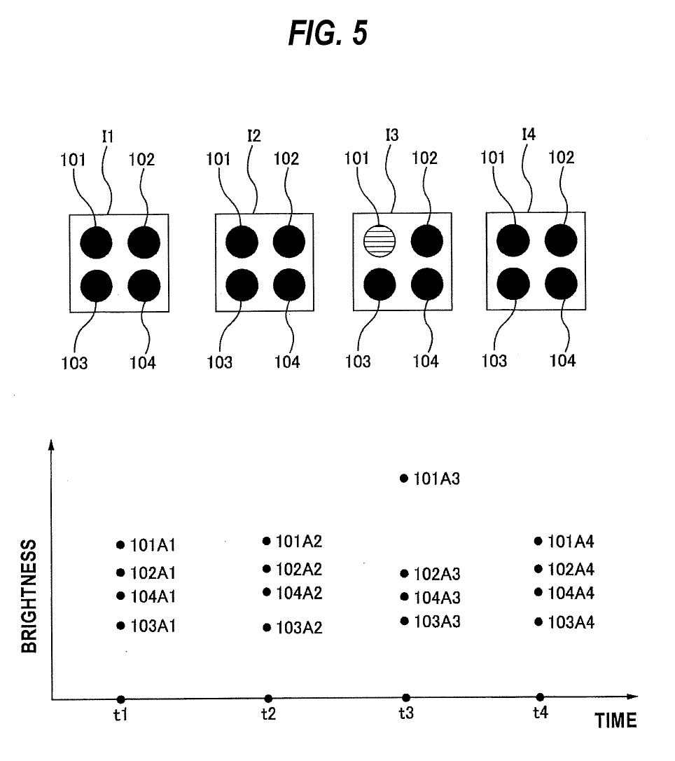

FIG. 5 is a conceptual diagram of the step 2 shown in FIG. 3. The main control unit 1 calculates average brightness levels 101A1, 102A1, 103A1, 104A1 which are average values of brightness of the contact holes 101, 102, 103, 104 on the voltage contrast image I1. Similarly, the main control unit 1 calculates average brightness levels 101A2, 102A2, 103A2, 104A2 of the contact holes 101, 102, 103, 104 on the voltage contrast image 12, calculates average brightness levels 101A3, 102A3, 103A3, 104A3 of the contact holes 101, 102, 103, 104 on the voltage contrast image I3, and calculates average brightness levels 101A4, 102A4, 103A4, 104A4 of the contact holes 101, 102, 103, 104 on the voltage contrast image I4.

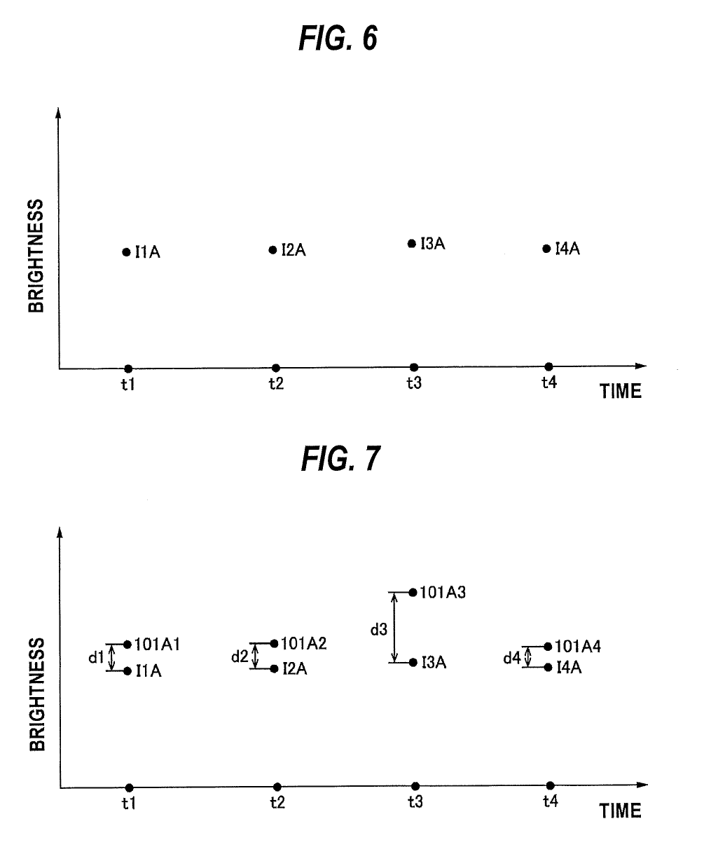

FIG. 6 is a conceptual diagram of the step 3 shown in FIG. 3. The main control unit 1 calculates a brightness index value I1A which is an average of all the average brightness levels 101A1 to 104A1 of the voltage contrast image I1. Similarly, the main control unit 1 calculates a brightness index value I2A which is an average of all the average brightness levels 101A2 to 104A2 of the voltage contrast image I2, calculates a brightness index value I3A which is an average of all the average brightness levels 101A3 to 104A3 of the voltage contrast image I3, and calculates a brightness index value I4A which is an average of all the average brightness levels 101A4 to 104A4 of the voltage contrast image I4.

FIG. 7 is a conceptual diagram of the step 4 shown in FIG. 3. The main control unit 1 calculates a difference d1 between the average brightness level 101A1 of the first contact hole 101 on the voltage contrast image I1 and the brightness index value I1A calculated for the voltage contrast image I1. Similarly, the main control unit 1 calculates a difference d2 between the average brightness level 101A2 of the first contact hole 101 on the voltage contrast image 12 and the brightness index value I2A calculated for the voltage contrast image I2, calculates a difference d3 between the average brightness level 101A3 of the first contact hole 101 on the voltage contrast image I3 and the brightness index value I3A calculated for the voltage contrast image I3, and calculates a difference d4 between the average brightness level 101A4 of the first contact hole 101 on the voltage contrast image I4 and the brightness index value I4A calculated for the voltage contrast image I4.

Further, the main control unit 1 calculates the sum of the differences d1, d2, d3, d4 calculated for the first contact hole 101 (step 5), and compares the calculated sum with the preset defect threshold value (step 6). If the sum of the differences is larger than the defect threshold value, the main control unit 1 determines that there is a defect in the first contact hole 101.

Similarly, the main control unit 1 calculates a difference between the average brightness level and the corresponding brightness index value for each of the second contact hole 102, the third contact hole 103, and the fourth contact hole 104, and compares the calculated difference with the defect threshold value.

According to the present embodiment, the brightness levels of the contact hole on the voltage contrast images generated at different points in time are used for detecting the defect of the contact hole. This enables the main control unit 1 to accurately detect the defect of the contact hole even if the brightness of the contact hole changes with time.

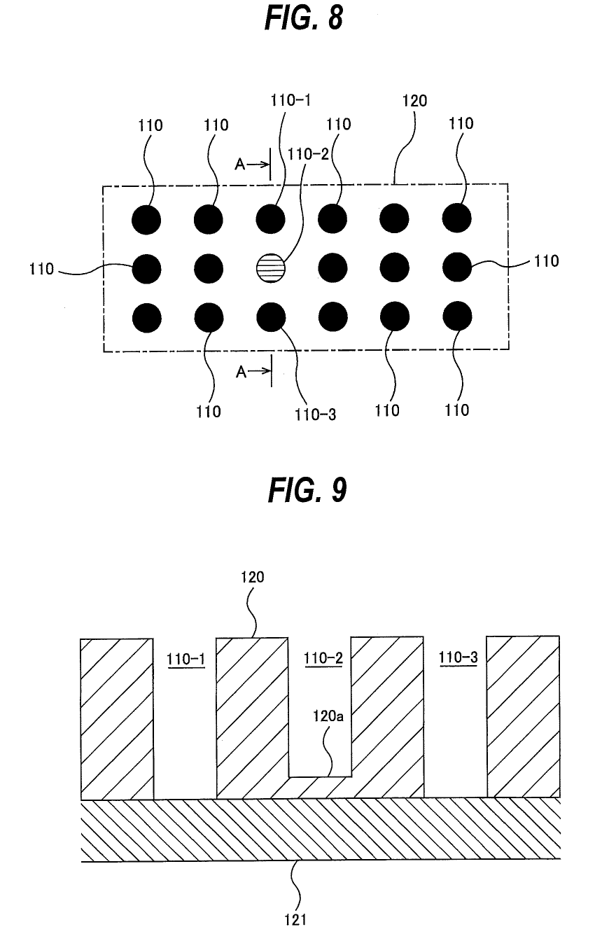

The brightness of the contact hole may change while the scanning electron microscope produces voltage contrast images. This phenomenon will be described with reference to FIGS. 8 to 13, which are conceptual diagrams illustrating the physical phenomenon of a change in brightness of each contact hole, in particular, a change in brightness in a case where residue of a dielectric film exists on a bottom of a contact hole. FIG. 8 is a plan view showing contact holes 110 formed in a dielectric film 120. As shown in FIG. 8, the contact holes 110 are arranged in a matrix.

FIG. 9 is a cross-sectional view taken along line A-A of FIG. 8. A conductive layer 121 lies under the dielectric film 120. A contact hole 110-2 does not extend through the dielectric film 120 and does not reach the underlying conductive layer 121. A residue 120a of the dielectric film 120 is present, thus forming a bottom of the contact hole 110-2.

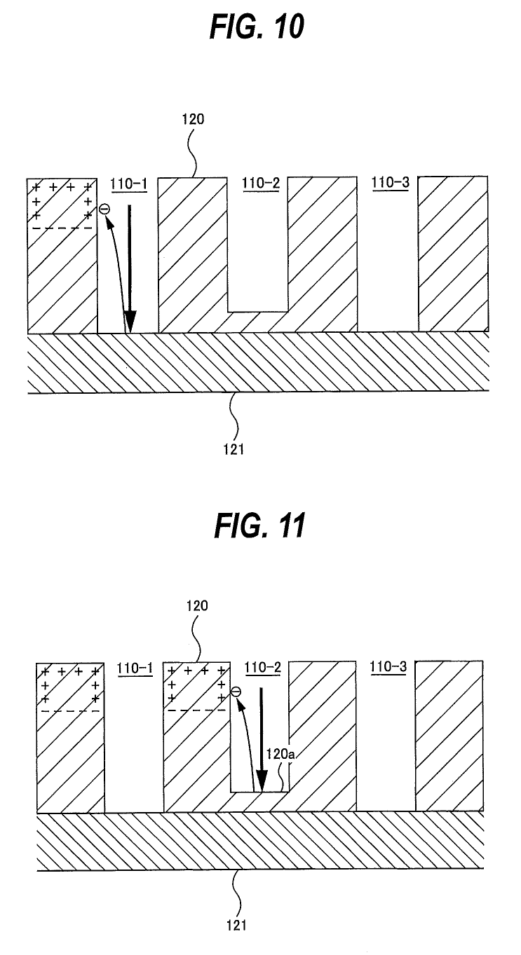

A voltage contrast image is generated by causing the electron beam to raster-scan the dielectric film 120 from an upper left to a lower right of the dielectric film 120 shown in FIG. 8. Therefore, as shown in FIG. 10, at the beginning of generation of the voltage contrast image, due to the irradiation of the electron beam, a positively charged layer is formed in the dielectric film 120 at the left side of the contact hole 110-1, and a negatively charged layer is formed in a middle portion of the dielectric film 120. This is due to the characteristic of the electron beam. On the other hand, since the electron beam is not yet directed to the dielectric film 120 at the right side of the contact hole 110-1, a positively charged layer and a negatively charged layer are not formed.

Secondary electrons are generated by the electron beam striking the bottom of the contact hole 110. When the secondary electrons are detected by the secondary electron detector 30 (see FIG. 2), the brightness of the contact hole 110 on the voltage contrast image increases. However, in the case shown in FIG. 10, due to the positively charged layer, a potential difference exists between a side surface of the dielectric film 120 at the left side of the contact hole 110-1 and a side surface of the dielectric film 120 at the right side of the contact hole 110-1. The secondary electrons are attracted to the side surface of the dielectric film 120 at the left side where the positively charged layer is formed, and do not reach the secondary electron detector 30. As a result, the brightness of the contact hole 110-1 on the voltage contrast image is low.

FIG. 11 is a schematic diagram showing a state immediately after the electron beam is directed to the contact hole 110-2 in which the residue 120a of the dielectric film 120 exists on the bottom. The residue 120a of the dielectric film 120 is present on the bottom of the contact hole 110-2. Generally, a dielectric material emits more secondary electrons than a conductive material. Therefore, when the residue 120a is irradiated with the electron beam, many secondary electrons are emitted from the bottom of the contact hole 110-2. However, a potential difference exists in the dielectric film 120 between the left side and the right side of the contact hole 110-2. As a result, the secondary electrons are attracted to the side surface of the dielectric film 120 at the left side where the positively charged layer is formed, and do not reach the secondary electron detector 30. Consequently, the brightness of the contact hole 110-2 on the voltage contrast image is low.

FIG. 12 is a schematic diagram showing a state in which the potential difference in the dielectric film 120 has disappeared as a result of continuously generating voltage contrast images. Secondary electrons emitted from the bottoms of the contact hole 110-1 and the contact hole 110-2 are not attracted to the side surfaces of the dielectric film 120 because there is no potential difference. Therefore, the secondary electrons, which have passed through the repulsion from the negatively charged layer in the middle portion of the dielectric film 120, are accelerated upward by the positively charged layer existing in the upper portion of the dielectric film 120, and are then detected by the secondary electron detector 30. Since the residue 120a of the dielectric film 120 is present at the bottom of the contact hole 110-2, more secondary electrons are emitted from the bottom of the contact hole 110-2. As a result, the brightness of the contact hole 110-2 on the voltage contrast image is high.

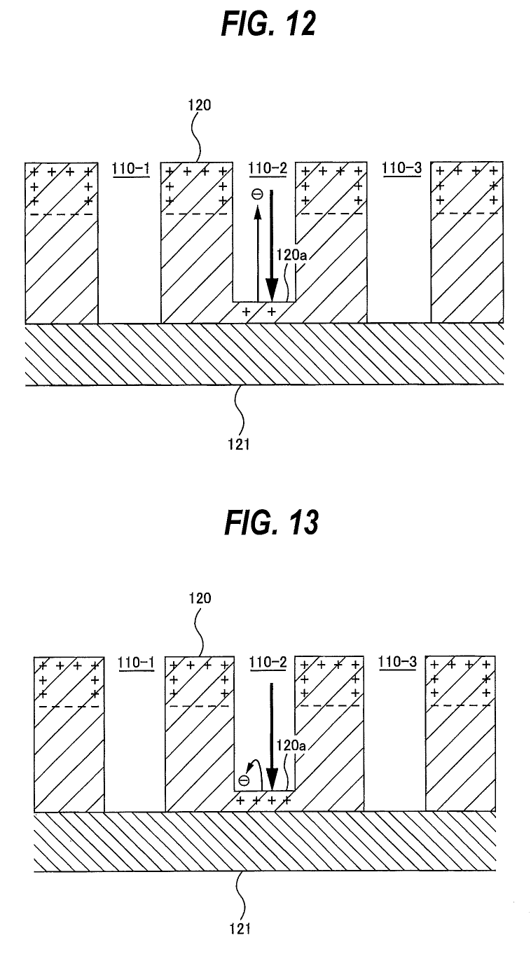

FIG. 13 is a schematic view showing a state in which a positively charged layer is formed in the residue 120a of the dielectric film 120 constituting the bottom of the contact hole 110-2 as a result of still continuing generation of the voltage contrast images. Secondary electrons generated by the electron beam irradiation on the contact hole 110-2 are attracted to the positively charged layer in the residue 120a and do not reach the secondary electron detector 30. As a result, the brightness of the contact hole 110-2 on the voltage contrast image is low.

With such a mechanism, the brightness of the defective contact hole in the voltage contrast image changes with the generation time of the voltage contrast images. According to the present embodiment, brightness values of contact holes on voltage contrast images that have been generated at different points in time are used for defect detection of a contact hole. As a result, even if the brightness of the contact hole fluctuates over time, the main control unit 1 can accurately detect the defect of the contact hole.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A method of detecting a defect of a contact hole, comprising:
obtaining a plurality of voltage contrast images generated at different points in time;
calculating average brightness levels of respective contact holes on each of the plurality of voltage contrast images;
calculating a brightness index value which is an average of the average brightness levels of respective contact holes on each of the plurality of voltage contrast images;
calculating a difference between an average brightness level of each contact hole on each voltage contrast image and the brightness index value that has been calculated for that voltage contrast image;
calculating a sum of the differences that have been calculated for contact holes located at the same position in the plurality of voltage contrast images;
comparing the sum of the differences with a defect threshold value; and
detecting a defect of a contact hole with which the sum of the differences is larger than the defect threshold value.

2. The method according to claim 1, wherein said obtaining the plurality of voltage contrast images comprises obtaining a plurality of voltage contrast images generated at constant time intervals within a preset period of time.
